(19) United States
(12) Patent Application Publication
(10) Pub. No.: US 2026/0143980 A1
(43) Pub. Date: May 21, 2026

(54) ANGLED ION IMPLANT TO ENABLE VOID-FREE FILLING OF HIGH ASPECT RATIO TRENCH

(71) Applicant: Applied Materials, Inc., Santa Clara, CA (US)

(72) Inventors: Sipeng Gu, Lexington, MA (US); Wei Zou, Lexington, MA (US); Kyu-Ha Shim, Andover, MA (US)

(73) Assignee: Applied Materials, Inc., Santa Clara, CA (US)

(21) Appl. No.: 18/952,373

(22) Filed: Nov. 19, 2024

(51) Int. Cl. H01L 21/265; H01J 37/317; H01L 21/02

(52) U.S. Cl. CPC H10P 30/222; H01J 37/3171; H10P 14/20; H01J 2237/31705; H01J 2237/31711

(57) ABSTRACT

Disclosed herein are approaches for forming a void-free trench fill material in a high aspect ratio trench using an angled ion implant. In some embodiments, a method may include providing a trench in a substrate, the trench including a set of sidewalls connected by a bottom surface, and forming a suppressor layer along an upper portion of the set of sidewalls of the trench by directing ions of an ion beam into the set of sidewalls at a non-zero angle relative to a perpendicular extending from an upper surface of the substrate. The ions impact the upper portion of the set of sidewalls without impacting a lower portion of the set of sidewalls.

### FIELD OF THE DISCLOSURE

The present embodiments relate to semiconductor device patterning and, more particularly, to an approach for forming a void-free trench fill material in a high aspect ratio trench using an angled ion implant.

### BACKGROUND OF THE DISCLOSURE

Semiconductor wafer processing may involve forming and filling trenches in semiconductor wafers or substrates. Filling trenches in a semiconductor wafer or substrate with a material may be referred to as “gap fill.” As trench widths become narrower and trench aspect ratios increase, the process of filling trenches becomes more challenging.

One existing gap fill method involves deposition of the fill material via epitaxy, chemical vapor deposition (CVD), atomic layer deposition (ALD), plasma-enhanced chemical vapor deposition (PECVD), or physical vapor deposition (PVD). Epitaxy, CVD, ALD, PECVD, and PVD methods of filling trenches typically result in deposition of more material on the upper sidewalls of the trenches than on the bottom and lower sidewalls of the trenches. Such methods also result in more deposited material on the top surfaces adjacent to the trenches. The uneven deposition often forms overhangs, which can cause the trench openings to close prior to completely filling the gap, resulting in voids or gaps.

Another existing method includes bottom-up epitaxial growth of the gap fill material within the trenches. Often there are no voids or gaps in the epitaxially grown material when the aspect ratio of the trench is below approximately 25:1. However, with aspect ratios approaching approximately 50:1 in some cases, seams and voids appear in the gap fill material, which ultimately impacts switching speed and results in reliability issues.

With respect to these and other considerations the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a trench in a substrate, the trench including a set of sidewalls connected by a bottom surface, and forming a suppressor layer along an upper portion of the set of sidewalls of the trench by directing ions of an ion beam into the set of sidewalls at a non-zero angle relative to a perpendicular extending from an upper surface of the substrate. The ions may impact the upper portion of the set of sidewalls without impacting a lower portion of the set of sidewalls.

In another aspect, a method of forming a trench fill material within a trench may include providing the trench in a substrate, the trench including a set of sidewalls connected by a bottom surface, and forming a suppressor layer along an upper portion of the set of sidewalls of the trench by directing ions of an ion beam into the set of sidewalls at a non-zero angle relative to a perpendicular extending from an upper surface of the substrate. The ions may impact the upper portion of the set of sidewalls without impacting a lower portion of the set of sidewalls or the bottom surface.

In yet another aspect, a method of forming a transistor may include providing a trench in a substrate, the trench including a set of sidewalls connected by a bottom surface, and forming a suppressor layer along an upper portion of the set of sidewalls of the trench by directing ions of an ion beam through a mask and into the set of sidewalls at a non-zero angle relative to a perpendicular extending from an upper surface of the substrate. The ions may impact the upper portion of the set of sidewalls without impacting a lower portion of the set of sidewalls or the bottom surface.

### BRIEF DESCRIPTION OF THE DRAWINGS

The accompanying drawings illustrate exemplary approaches of the disclosure, including the practical application of the principles thereof, as follows:

FIG. 1A is a top view of a device including a trench formed in a substrate, according to embodiments of the present disclosure;

FIG. 1B is a cross-sectional side view, along cutting plane X-X′ of FIG. 1A, of the device including the trench formed in the substrate, according to embodiments of the present disclosure;

FIG. 2A is a top view of the device including a suppressor layer formed in the trench, according to embodiments of the present disclosure;

FIG. 2B is a cross-sectional side view, along cutting plane X-X′ of FIG. 2A, of the device including a suppressor layer formed in the trench, according to embodiments of the present disclosure;

FIG. 3 is a cross-sectional side view illustrating the device following formation of a fill material within the trench, according to embodiments of the present disclosure;

FIG. 4 is a cross-sectional side view illustrating the device following further formation of the fill material within the trench, according to embodiments of the present disclosure;

FIG. 5 is a cross-sectional side view illustrating the device following removal of a mask and a portion of the fill material, according to embodiments of the present disclosure;

FIG. 6 illustrates a schematic diagram of a processing apparatus according to embodiments of the present disclosure; and

FIG. 7 shows a semiconductor processing apparatus according to embodiments of the disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, devices, and systems in accordance with the present disclosure will now be described more fully hereinafter with reference to the accompanying drawings, where various embodiments are shown. The methods, devices, and systems may be embodied in many different forms and are not to be construed as being limited to the embodiments set forth herein. Instead, these embodiments are provided so the disclosure will be thorough and complete, and will fully convey the scope of the methods to those skilled in the art.

Embodiments described herein provide a void-free trench fill process in which an angled ion beam is directed into one or more high aspect ratio (AR) trenches to form a suppressor layer (e.g., oxide) along an upper portion of the sidewalls of the trenches without forming the suppressor layer along a lower portion of the sidewalls or along a bottom surface of the trenches. When the fill material is formed within the trenches, e.g., using a bottom-up growth process, the suppression layer prevents, or slows, epitaxial growth of the fill material in the upper portion of the trenches, thus eliminating voids or seams from being formed therein.

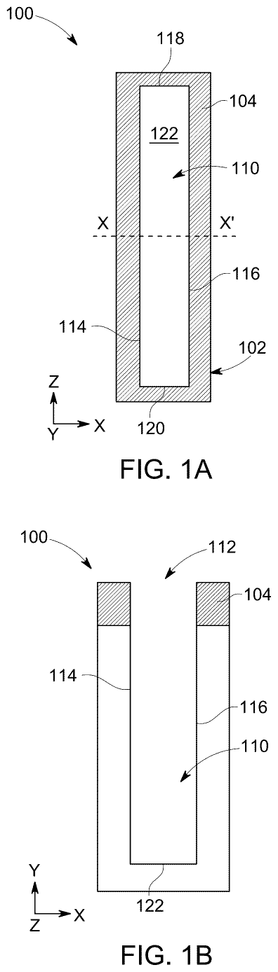

FIG. 1A is a top view and FIG. 1B is a side cross-sectional view of a semiconductor device structure (hereinafter “device”) 100, such as a portion of a metal-oxide-semiconductor field-effect transistor (MOSFET), according to one or more embodiments described herein. The device 100 may include a substrate 102 and a mask 104 formed over the substrate 102. The substrate 102 may be a bulk material, such as silicon, or may represent a layer of a given material, such as a layer of silicon, oxide, nitride, or other material, where the layer is disposed on another material, such as a substrate base. The substrate base (not separately shown) may in turn include any number of layers and structures. Embodiments herein are not limited in this context.

As further shown, one or more trenches 110 may be formed inside the substrate 102, through an opening 112 of the mask 104. The trench 110 may be defined by a first sidewall 114 opposite a second sidewall 116, and a first end 118 opposite a second end 120. A bottom surface 122 extends between the sidewalls. In some embodiments, the trench 110 may be formed using an etch process, and may have a high aspect ratio, i.e., a ratio of a depth or height in the y-direction to a width in the x-direction greater than 20. In some examples, the aspect ratio may be greater than or equal to 50. The trenches 110 illustrated may have a substantially vertical profile, or may have sidewalls with tapered or other profiles.

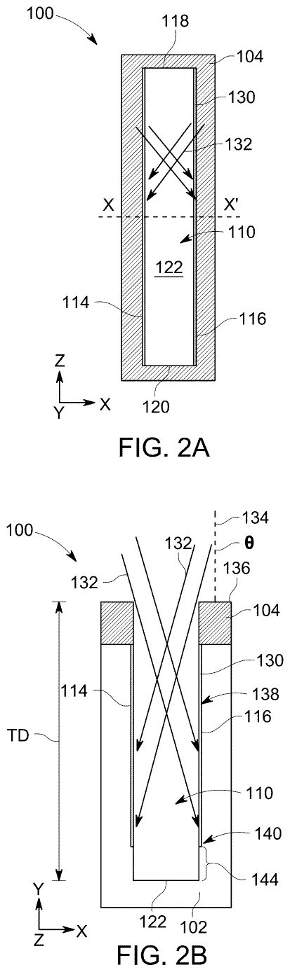

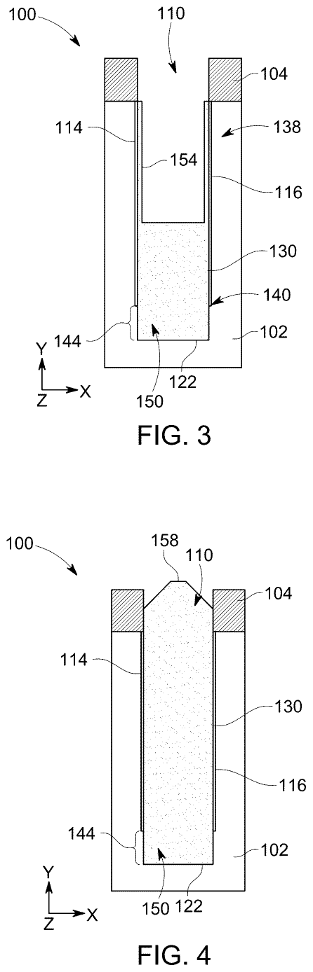

As shown in FIGS. 2A-2B, a suppressor layer 130 may then be formed within the trench 110 by performing an angled ion implant in which ions 132 are directed at a non-zero angle (θ) relative to a perpendicular 134 extending from a top surface 136 of the mask 104. More specifically, the ions 132 may be directed into an upper portion 138 of the first sidewall 114 and the second sidewall 116, while the ions 132 are prevented from impacting a lower portion 140 of the first sidewall 114 and the second sidewall 116, and from impacting the bottom surface 122 of the trench 110. The suppressor layer 130 may be further prevented from being formed along the first end 118 or the second end 120 of the trench 110 in some embodiments.

Although non-limiting, the non-zero angle (θ) may be between 5°-20°, and the ions 132 may be delivered at an energy between approximately 100 eV and 10 keV in some non-limiting embodiments. Furthermore, the dose of the ion implant may be between approximately 1E15-1E18 cm-2. In some embodiments, the ions 132 are oxygen, thus forming a thin oxide (e.g., SiO) layer along the first sidewall 114 and the second sidewall 116. In other embodiments, the ions 132 may include other species like nitrogen, carbon, etc. In still other embodiments, the ion implant may include a co-implant with multiple species to form the suppressor layer 130. The suppressor layer 130 may have a thickness, in the x-direction, of approximately 10 nm, which may decrease to approximately 7-8 nm in the case a native oxide clean process is employed following formation. The oxide thickness may vary depending on device design. Advantageously, the aspect ratio of the trench 110 does not significantly increase as a result of the presence of the suppressor layer 130 along the first sidewall 114 and the second sidewall 116.

As shown, the lower portion 140 includes an area 144 that remains uncovered by the suppressor layer 130. In one non-limiting embodiment, a height or vertical distance, in the y-direction, of the area 144 may be between 30-50 um, while the height of the suppressor layer 130 may be greater than 100 um. Meanwhile, a trench width, as measured horizontally between the first sidewall 114 and the second sidewall 116, may be approximately 30 um, and a height of the mask 104 may be between 20-50 um. Therefore, a ratio of the total trench depth ‘TD’ to the height of the area 144, at the time of the ion implant, may be approximately 5:1.

In some embodiments, a stage or platform upon which the device 100 is positioned may rotate as part of the angled ion implant process. Platform rotation may enable impacting the first and second sidewalls 114, 116 with the ions 132. In one embodiment, the ion beam treats the first sidewall 114, the platform is rotated by 180 degrees, and the ion beam then treats the second sidewall 116. In other embodiments, the device 100 may be rotated by 90, 180, and 270 degrees between each implant. Embodiments herein are not limited in this context.

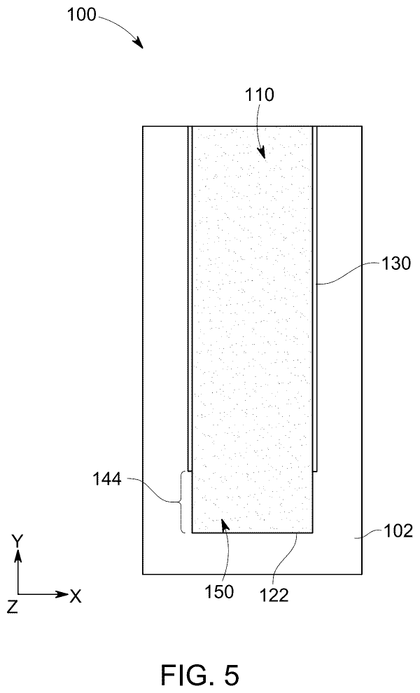

Next, as shown in FIG. 4, a fill material 150 may then be formed within the trench 110. In some embodiments, the fill material 150 may be formed using an epitaxial, bottom-up anisotropic fill process in which the fill material 150 (e.g., Si) may be formed directly atop the bottom surface 122 and along the area 144 beneath the suppressor layer 130. As demonstrated, the fill material 150 may be formed primarily along the lower portion 140 of the first and second sidewalls 114, 116. The fill material 150 is initially inhibited by the suppressor layer 130 from growing along the upper portion 138 of the first and second sidewalls 114, 116. In some embodiments, a thin layer 154 of the fill material 150 may be formed along the suppressor layer 130, extending to the mask 104. The fill material 150 may continue to be deposited within the trench, as shown in FIG. 4, followed by a planarization process to remove the mask 104 and a tip 158 of the fill material 150, as shown in FIG. 5.

In various embodiments, the fill material 150 is advantageously formed within each trench 110 without any voids, gaps, seams, etc. In various such embodiments, the fill material 150 may comprise a bottom-up fill, which grows or builds up from the area 144 left uncovered by the suppressor layer 130 and from the bottom surface 122 at the base of the trench 110. In other words, the fill material 150 advantageously grows seamlessly up from the bottom surface 122 during the deposition process. In some embodiments, the fill material 150 may be deposited over the device 100 including into the trench 110, via Epitaxy, ALD or CVD, resulting in bulk Epitaxy, ALD or CVD growth. In yet other embodiments, the fill material 150 may be formed via electrodeposition.

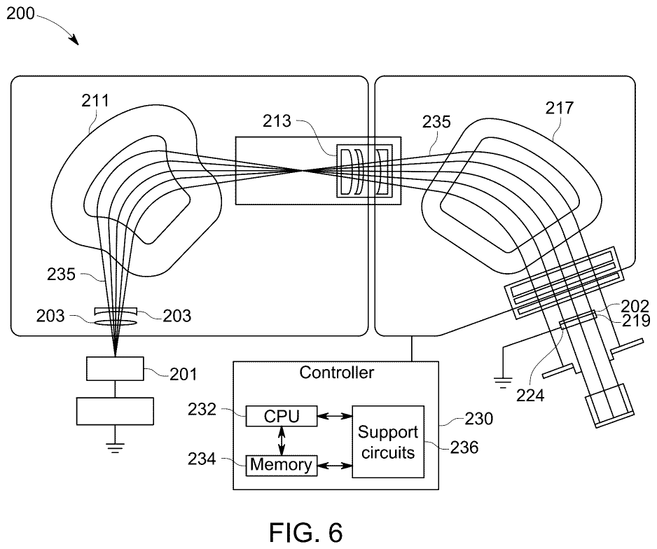

FIG. 6 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the angled ions 132 from the ion beam demonstrated in FIGS. 2A-2B.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. In some embodiments, the platen 219 may be heated using an external or embedded heating element 224, such as a resistive heater, or may be heated using radiant heat, such as heating lamps disposed above or below the platen 219. In other embodiments, the heating element may additionally, or alternatively, be located in a load lock chamber or a separate pre-heat chamber to pre-heat the wafer 202 before it reaches the platen 219. Even with a pre-heat, the platen 219 may include the internal heating element 224. The substrate 202 may be the same as the substrate 102 described above. The substrate 202 may be moved in one or more dimensions (e.g. translate, rotate, tilt, etc.) by a component sometimes referred to as a “roplat” (not shown). It is also contemplated that the processing apparatus 200 may be configured to perform heated implantation processes to provide for improved control of implantation characteristics, such as the ion trajectory and implantation energy utilized to dope the substrate.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

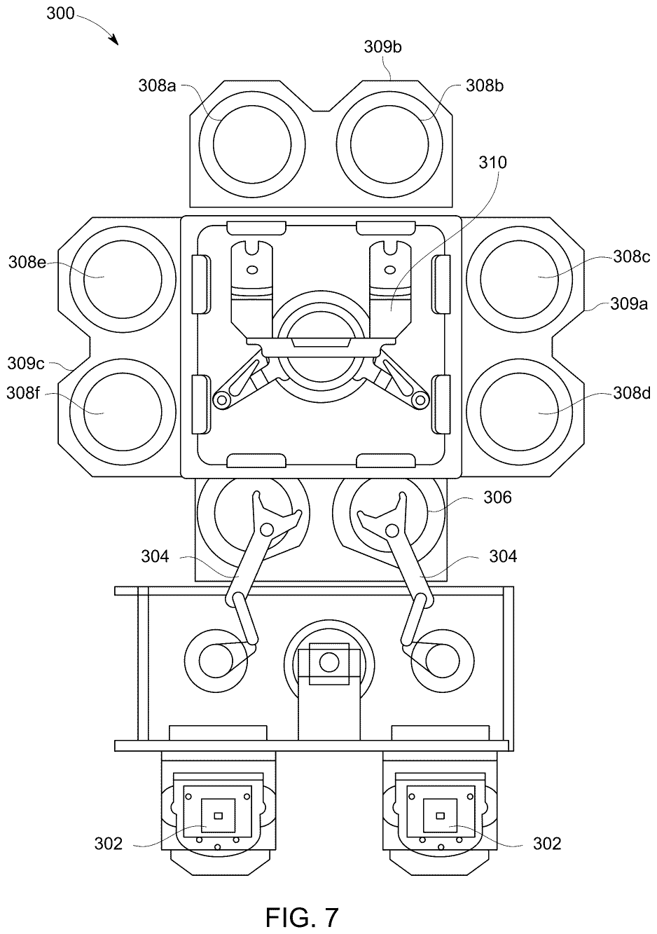

FIG. 7 illustrates a top plan view of one embodiment of another processing system 300 including a plurality of chambers according to some embodiments. As shown, a pair of front opening unified pods 302 supply substrates of a variety of sizes that are received by robotic arms 304 and placed into a low-pressure holding area 306 before being placed into one of the substrate processing chambers 308a-f, positioned in tandem sections 309a-c. A second robotic arm 310 may be used to transport the substrate wafers from the holding area 306 to the substrate processing chambers 308a-f and back. Each substrate processing chamber, 308a-f, can be outfitted to perform a number of substrate processing operations described herein such as ion implant, pre-clean, anneal, plasma processing, degas, orientation, and other substrate processes.

The substrate processing chambers 308a-f may include one or more system components for depositing, treating, growing, annealing, curing, implanting, and/or etching the substrate and/or a material layer on the substrate or wafer. In one configuration, two pairs of the processing chambers, for example 308a-b, may be used treat the substrate and/or the material layers formed atop the substrate using a beamline ion implant. Another two pairs of the processing chambers, for example, 308c-d, may be used to treat the substrate and/or the material layers formed atop the substrate using a plasma doping (PLAD) process. In some embodiments, the PLAD process may be performed in a pre-clean chamber. Another two pairs of the processing chambers, for example, 308e-f, may be used to epitaxially grow material on the substrate. More specifically, processing chambers 308e-f may be configured as a selective epitaxial growth chamber for performing one or more different epitaxial growth processes. In another configuration, all three pairs of chambers, for example 308a-f, may be configured to epitaxially grow material and treat the substrate/material on the substrate.

Any one or more of the processes described may be carried out in additional chambers separated from the fabrication system shown in different embodiments. It will be appreciated that additional configurations of deposition, treating, growing, etching, annealing, and curing chambers for substrates and material layers are contemplated by the processing system 300. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The processing system 300, or more specifically, chambers incorporated into the processing system 300 or other processing systems, may be used to produce structures according to some embodiments of the present disclosure.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a trench in a substrate, the trench including a set of sidewalls connected by a bottom surface; and
forming a suppressor layer along an upper portion of the set of sidewalls of the trench by directing ions of an ion beam into the set of sidewalls at a non-zero angle relative to a perpendicular extending from an upper surface of the substrate, wherein the ions impact the upper portion of the set of sidewalls without impacting a lower portion of the set of sidewalls.

2. The method of claim 1, wherein the ions are prevented from impacting the bottom surface of the trench.

3. The method of claim 1, further comprising forming a trench fill material within the trench.

4. The method of claim 3, wherein the trench fill material is formed using a bottom-up growth process.

5. The method of claim 1, wherein forming the suppressor layer comprises directing oxygen ions into the set of sidewalls to form an oxide layer along the upper portion of the set of sidewalls.

6. The method of claim 1, further comprising providing a mask over the substrate, wherein the ions of the ion beam are delivered through an opening of the mask.

7. The method of claim 1, wherein the trench further comprises a first end opposite a second end, and wherein the ions impact the set of sidewalls of the trench without impacting the first end or the second end of the trench.

8. The method of claim 1, wherein the non-zero angle is between 5°-20°.

9. A method of forming a void-free trench fill material within a trench, the method comprising:
providing the trench in a substrate, the trench including a set of sidewalls connected by a bottom surface; and
forming a suppressor layer along an upper portion of the set of sidewalls of the trench by directing ions of an ion beam into the set of sidewalls at a non-zero angle relative to a perpendicular extending from an upper surface of the substrate, wherein the ions impact the upper portion of the set of sidewalls without impacting a lower portion of the set of sidewalls and without impacting the bottom surface.

10. The method of claim 9, further comprising forming a trench fill material within the trench after forming the suppressor layer.

11. The method of claim 10, wherein the trench fill material is formed using an anisotropic bottom-up growth process.

12. The method of claim 9, wherein forming the suppressor layer comprises directing at least one of the following ion species into the set of sidewalls: oxygen, nitrogen, and carbon.

13. The method of claim 9, further comprising providing a mask over the substrate, wherein the ions of the ion beam are delivered through an opening of the mask.

14. The method of claim 9, wherein the trench further comprises a first end opposite a second end, and wherein the ions impact the set of sidewalls of the trench without impacting the first end or the second end of the trench.

15. The method of claim 9, wherein the non-zero angle is between 5°-20°.

16. A method of forming a transistor, comprising:
providing a trench in a substrate, the trench including a set of sidewalls connected by a bottom surface; and
forming a suppressor layer along an upper portion of the set of sidewalls of the trench by directing ions of an ion beam through a mask and into the set of sidewalls at a non-zero angle relative to a perpendicular extending from an upper surface of the substrate, wherein the ions impact the upper portion of the set of sidewalls without impacting a lower portion of the set of sidewalls or the bottom surface.

17. The method of claim 16, further comprising forming a trench fill material within the trench after forming the suppressor layer.

18. The method of claim 17, wherein the trench fill material is formed using an anisotropic bottom-up growth process.

19. The method of claim 16, wherein forming the suppressor layer comprises directing oxygen ions into the set of sidewalls to form a silicon oxide layer along the upper portion of the set of sidewalls.

20. The method of claim 16, wherein the trench further comprises a first end opposite a second end, and wherein the ions impact the set of sidewalls of the trench without impacting the first end or the second end of the trench.
